(19) United States
(12) Patent Application Publication
(10) Pub. No.: US 2013/0256705 A1
(43) Pub. Date: Oct. 3, 2013

(54) LIGHT EMITTING DIODE LIGHT BAR STRUCTURE

(71) Applicant: Jianfa Huang, Shenzhen (CN)

(72) Inventor: Jianfa Huang, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/574,249

(22) PCT Filed: Apr. 5, 2012
(86) PCT No.: PCT/CN2012/073540

§ 371 Date: Jul. 20, 2012

(30) Foreign Application Priority Data
Mar. 30, 2012 (CN) 201210090537.2

(51) Int. Cl. H01L 33/08

(52) U.S. Cl. 257/88; 257/E33.055

(57) ABSTRACT

The present invention discloses a light emitting diode (LED) light bar structure, which is applied to a backlight module of edge lighting. The LED light bar structure comprises a circuit board, a first row light source and a second row light source. The first row light source comprises a plurality of first LEDs; the second row light source comprises a plurality of second LEDs; and the first LEDs of the first row light source alternately continue with the second LEDs of the second row light source along the longitude direction of the circuit board to keep the lights entering into the light guide plate continuously, so as to prevent the light guide plate from light shadow “Mura” phenomenon in the light guide plate near the LEDs, and it can suit the design trend of narrow frame of liquid crystal panel.

### FIELD OF THE INVENTION

The present invention relates to a light emitting diode (LED) light bar structure, and more particularly to an LED light bar structure which has a plurality of rows of LEDs to alternately continue with each other along the longitude direction of the circuit board.

### BACKGROUND OF THE INVENTION

A liquid crystal display (LCD) is a kind of flat panel display (FPD) which displays images by the property of the liquid crystal material. In comparison with other display devices, the LCD has the advantages in lightweight, compactness, low driving voltage and low power consumption, and thus has already become the mainstream product in the whole consumer market. However, the liquid crystal material of the LCD cannot emit light by itself, and must depend upon an external light source. Thus, the LCD further has a backlight module to provide the needed light source.

Generally speaking, backlight modules have been developed based on size requirements into a type of edge lighting structures and another type of bottom lighting structures, which are categorized by locations of lamp tubes thereof. A light source of the type of edge lighting structures is a single light source placed aside, and a light source of the type of bottom lighting structures is placed right beneath. The lamp tubes of the backlight modules must be featured with high brightness and a long lifespan, etc. They currently include cold cathode fluorescent lamps (CCFL), hot cathode fluorescent lamps, light emitting diodes (LED) and electroluminescence (EL), etc.

Among them, the CCFL has characters of high luminance, high efficiency, a long lifespan, and high color rendering, etc. Besides, it is much easier to be assembled with light reflection components to form a thin-sheet lighting device due to its cylinder shape. Therefore, using the CCFL as main backlight sources was once a main trend for making backlight modules. However, the CCFL is gradually eliminated by the present trend of soaring environmental awareness today due to its filled content of mercury vapors. Since using LED as backlight sources has an advantage of energy saving and environmental protection over the CCFL, it becomes a trend in backlight development to replace the CCFL by the LED. A lighting structure of the LED is generally called as a light bar in practice.

Referring to FIG. 1, a schematic view showing a currently existing LED light bar emits lights into a light guide plate is illustrated in FIG. 1. As shown in FIG. 1, a LED light bar structure 90 comprises a circuit board 91 of a substantially long strap shape and a plurality of LEDs 92. The LEDs 92 are arranged on an upper surface of the circuit board 91 and fixed thereon through a plurality of solder points (not shown) to be electrically connected with the circuit board 91. The LEDs 92 emit lights toward a side edge of a light guide plate 80, and then emit lights toward a top surface of the light guide plate by special reflection of the light guide plate. Although using LEDs as the backlight source has advantages of lightness and thinness, environmental protection, electricity saving, and so on, the aforementioned existing LED light bar still has a few problems.

Because the refractive index of the light guide plate 80 (about 1.42-1.50) is larger than the refractive index of air, when the lights from the LED 92 enter into the light guide plate 80, the refraction angle of the lights will become smaller, and all of the refracted lights is limited within 42° taper shape, so such character causes the brightness does not uniform in the light guide plate 80 near the LED 92, it also called of light shadow “Mura” phenomenon. For avoiding the “Mura” phenomenon, a general method is to add the width of a side edge frame, so as to cover the light shadow “Mura”. However, when the market is trended toward the narrow frame, how to solve the light shadow “Mura” is become the key technology of achieving the narrow frame.

As a result, it is necessary to provide an LED light bar structure to solve the problems existing in the conventional technologies.

### SUMMARY OF THE INVENTION

A primary object of the present invention is to provide a light emitting diode (LED) light bar structure to solve the problem existing in the conventional technologies that it is easy appeared a “Mura” phenomenon in the light guide plate near the LEDs.

To achieve the above object, the present invention provides an LED light bar structure, which comprises:

a circuit board disposed at a side edge of a light guide plate and emitting lights toward the light guide plate;

a first row light source including a plurality of first LEDs arranged as one row by spacing a first interval; and

a second row light source including a plurality of second LEDs arranged as one row by spacing a second interval;

wherein the first LEDs of the first row light source alternately continue with the second LEDs of the second row light source along the longitude direction of the circuit board, so as to keep the lights entering into the light guide plate continuously; the first interval is equal to the length of the second LEDs; and the second interval is equal to the length of the fist LEDs.

To achieve the above object, the present invention further provides an LED light bar structure, which comprises:

a circuit board disposed at a side edge of a light guide plate and emitting lights toward the light guide plate;

a first row light source including a plurality of first LEDs arranged as one row by spacing a first interval; and

a second row light source including a plurality of second LEDs arranged as one row by spacing a second interval;

wherein the first LEDs of the first row light source alternately continue with the second LEDs of the second row light source along the longitude direction of the circuit board, so as to keep the lights entering into the light guide plate continuously.

To achieve the above object, the present invention further provides a backlight module, which comprises:

a circuit board disposed at a side edge of a light guide plate and emitting lights toward the light guide plate;

a first row light source including a plurality of first LEDs arranged as one row by spacing a first interval;

a second row light source including a plurality of second LEDs arranged as one row by spacing a second interval; and

a third row light source including a plurality of third LEDs corresponding to the first LEDs of the first row light source;

wherein the second row light source is between the first row light source and the third row light source, and the first LEDs of the first row light source and the third LEDs of the third row light source alternately continue with the second LEDs of the second row light source along the longitude direction of the circuit board, so as to keep the lights entering into the light guide plate continuously.

In one embodiment of the present invention, the first interval is equal to or smaller than the length of the second LEDs.

In one embodiment of the present invention, the second interval is equal to or smaller than the length of the first LEDs.

In one embodiment of the present invention, the length of the fist LEDs is larger than the length of the second LEDs.

In one embodiment of the present invention, the length of the fist LEDs is smaller than the length of the second LEDs.

Hence, in the present invention, the first LEDs of the first row light source alternately continue with the second LEDs of the second row light source along the longitude direction of the circuit board to keep the lights entering into the light guide plate continuously, so as to prevent the light guide plate from light shadow “Mura” phenomenon in the light guide plate near the LEDs, and it can suit the design trend of narrow frame of liquid crystal panel.

### DESCRIPTION OF THE DRAWINGS

FIG. 1 is a schematic view showing a currently existing LED light bar emits lights into a light guide plate;

FIG. 2 is a schematic view showing a light emitting diode (LED) light bar according to a first embodiment of the present invention emits lights into a light guide plate;

FIG. 3 is a front view of the light bar structure according to the first embodiment of the present invention;

FIG. 4 is a front view of an LED light bar structure according to the second embodiment of the present invention;

FIG. 5 is a front view of an LED light bar structure according to the third embodiment of the present invention; and

FIG. 6 is a front view of an LED light bar structure according to the fourth embodiment of the present invention.

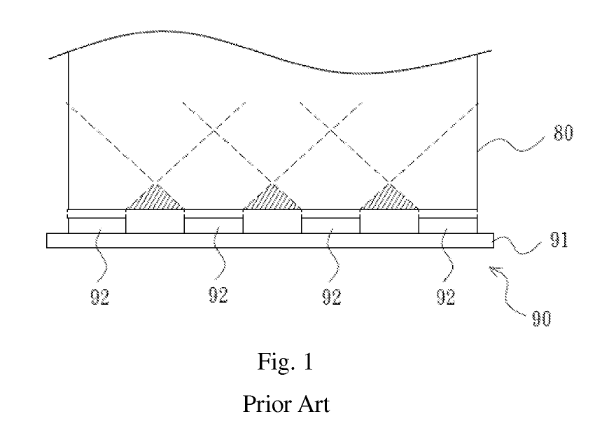

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

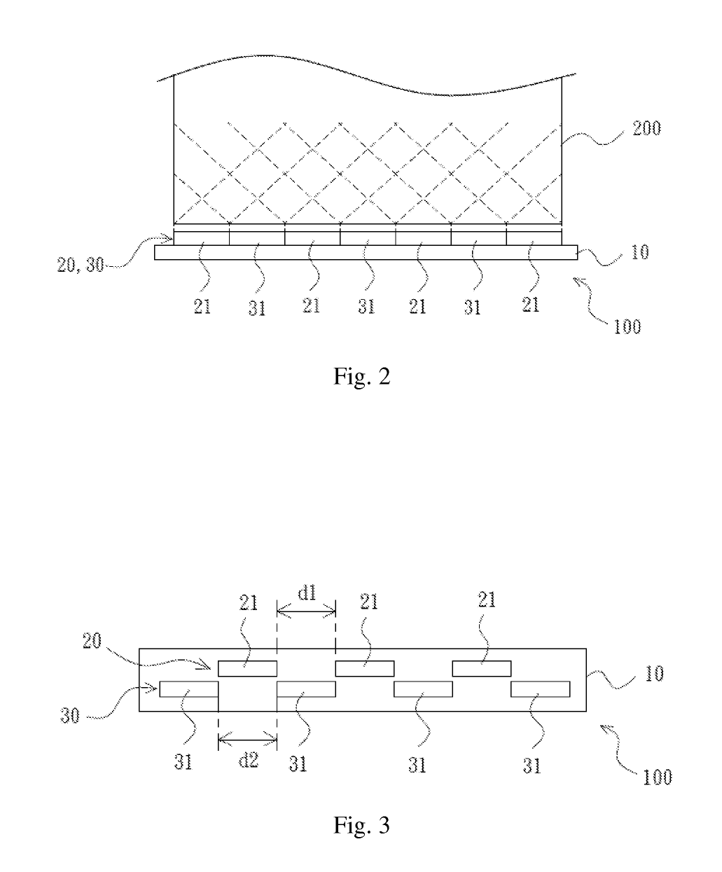

Referring now to FIGS. 2 and 3, a schematic view showing a light emitting diode (LED) light bar according to a first embodiment of the present invention emits lights into a light guide plate is illustrated in FIG. 2; and a front view of the light bar structure according to the first embodiment of the present invention is illustrated in FIG. 3. As shown in FIGS. 2 and 3, an LED light bar structure 100 according to the present invention comprises a circuit board 10, a first row light source 20 and a second row light source 30. The circuit board 10 is disposed at a side edge of a light guide plate 200, and emits lights toward the light guide plate 200. Besides, the first row light source 20 comprises a plurality of first LEDs 21 arranged as one row by spacing a first interval d1, and the second row light source 30 comprises a plurality of second LEDs 31 arranged as one row by spacing a second interval d2. Preferably, the first interval d1 is equal to the length of the second LEDs 31 (along the level direction in the figure); and the second interval d2 is equal to the length of the fist LEDs 21 (along the level direction in the figure).

Moreover, the first LEDs 21 of the first row light source 20 alternately continue with the second LEDs 31 of the second row light source 30 along the longitude direction of the circuit board 10, so that the first LEDs 21 and the second LEDs 31 is easy to electrically connect and fix with the circuit board 10 through a plurality of solder points or solder wires (not shown), and meanwhile, it can keep the lights entering into the light guide plate 200 continuously, so as to prevent the light guide plate 200 from light shadow “Mura” phenomenon in the light guide plate near the LED light bar structure 100, and it can suit the design trend of narrow frame of liquid crystal panel in present market.

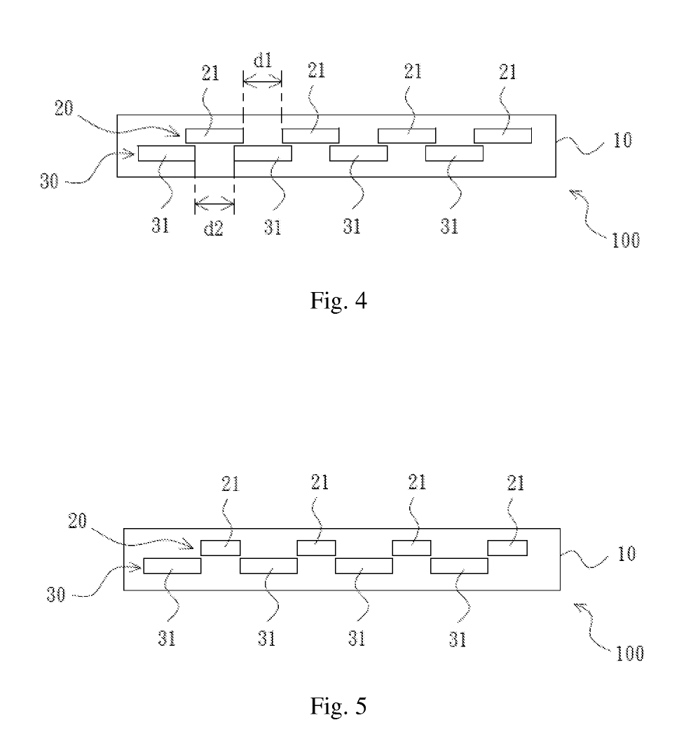

Referring to FIG. 4, a front view of an LED light bar structure according to the second embodiment of the present invention is illustrated in FIG. 4. The LED light bar construct 100 according to the second preferred embodiment of the present invention is substantially similar to the he LED light bar construct 100 according to the first preferred embodiment of the present invention, so as to use similar terms and numerals, but the difference therebetween is that: in this embodiment, the first interval d1 is smaller than the length of the second LEDs 31 (along the level direction in the figure); and the second interval d2 is smaller than the length of the fist LEDs 21 (along the level direction in the figure). In another word, the fist LEDs 21 and the second LEDs 31 is partly overlapped in perpendicular direction of the figure. If the present big size liquid crystal panel adopts the type of backlight of edge lighting, the intensity of the LED light bar can not always satisfy the emitting intensity requirement. Hence, the second preferred embodiment of the present invention except having the advantage of the first preferred embodiment, it has a characteristic of enhancing intensity of lights, so as to suit the backlight requirement of the big size liquid crystal panel.

Referring to FIG. 5, a front view of an LED light bar structure according to the third embodiment of the present invention is illustrated in FIG. 5. The LED light bar construct 100 according to the third preferred embodiment of the present invention is substantially similar to the LED light bar construct 100 according to the foregoing preferred embodiment of the present invention, so as to use similar terms and numerals, but the difference therebetween is that: in this embodiment, the length of the fist LEDs 21 is larger than the length of the second LEDs 31 (or the length of the fist LEDs 21 is smaller than the length of the second LEDs 31). In another word, the present invention can adopt two different specifications of LEDs for arrangement, so as to further increase the flexibility in selection and arrangement of the LEDs.

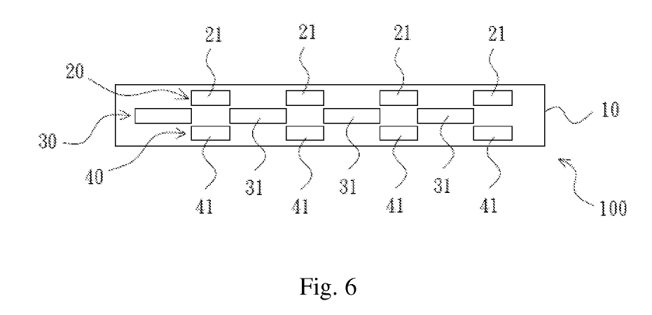

Referring to FIG. 6, a front view of an LED light bar structure according to the fourth embodiment of the present invention is illustrated in FIG. 6. The LED light bar construct 100 according to the fourth preferred embodiment of the present invention is substantially similar to the LED light bar construct 100 according to the foregoing preferred embodiment of the present invention, so as to use similar terms and numerals, but the difference therebetween is that: in this embodiment, the LED light bar construct 100 further comprises a third row light source 40, wherein the third row light source 40 comprises a plurality of third LEDs 41 corresponding to the first LEDs 21 of the first row light source 20. Besides, the second row light source 30 is between the first row light source 20 and the third row light source 40, and the first LEDs 21 of the first row light source 20 and the third LEDs 41 of the third row light source 40 alternately continue with the second LEDs 31 of the second row light source 30 along the longitude direction of the circuit board 10, so as to keep the lights entering into the light guide plate (not shown) continuously.

Hence, the fourth preferred embodiment of the present invention has advantages as follows: it can easy electrically connect and fix with the circuit board 10; it can keep the lights entering into the light guide plate 200 continuously; it can increase the flexibility in selection and arrangement of the LEDs; and it can enhance the intensity of lights to suit the backlight requirement of the big size liquid crystal panel.

As described above, in the traditional technology, when the lights from the LED enter into the light guide plate, the refraction angle of the lights will become smaller, and all of the refracted lights is limited within 42° taper shape, so as to causes a “Mura” phenomenon, and it is disadvantageous in the trended of the narrow frame. In the present invention, by that the first LEDs 21 of the first row light source 20 alternately continue with the second LEDs 31 of the second row light source 30 along the longitude direction of the circuit board 10, it can keep the lights entering into the light guide plate 200 continuously, so as to prevent the light guide plate 200 from light shadow “Mura” phenomenon in the light guide plate near the LEDs, and it can suit the design trend of narrow frame of liquid crystal panel.

The present invention has been described with a preferred embodiment thereof and it is understood that many changes and modifications to the described embodiment can be carried out without departing from the scope and the spirit of the invention that is intended to be limited only by the appended claims.

1. A light emitting diode (LED) light bar structure, comprising:
a circuit board disposed at a side edge of a light guide plate and emitting lights toward the light guide plate;
a first row light source including a plurality of first LEDs arranged as one row by spacing a first interval; and
a second row light source including a plurality of second LEDs arranged as one row by spacing a second interval;
wherein the first LEDs of the first row light source alternately continue with the second LEDs of the second row light source along the longitude direction of the circuit board, so as to keep the lights entering into the light guide plate continuously; the first interval is equal to the length of the second LEDs; and the second interval is equal to the length of the fist LEDs.

2. The LED light bar structure according to claim 1, wherein the length of the fist LEDs is larger than the length of the second LEDs.

3. The LED light bar structure according to claim 1, wherein the length of the fist LEDs is smaller than the length of the second LEDs.

4. An LED light bar structure, comprising:
a circuit board disposed at a side edge of a light guide plate and emitting lights toward the light guide plate;
a first row light source including a plurality of first LEDs arranged as one row by spacing a first interval; and
a second row light source including a plurality of second LEDs arranged as one row by spacing a second interval;
wherein the first LEDs of the first row light source alternately continue with the second LEDs of the second row light source along the longitude direction of the circuit board, so as to keep the lights entering into the light guide plate continuously.

5. The LED light bar structure according to claim 4, wherein the first interval is equal to the length of the second LEDs.

6. The LED light bar structure according to claim 4, wherein the first interval is smaller than the length of the second LEDs.

7. The LED light bar structure according to claim 4, wherein the second interval is equal to the length of the first LEDs.

8. The LED light bar structure according to claim 4, wherein the second interval is smaller than the length of the first LEDs.

9. The LED light bar structure according to claim 4, wherein the length of the fist LEDs is larger than the length of the second LEDs.

10. The LED light bar structure according to claim 4, wherein the length of the fist LEDs is smaller than the length of the second LEDs.

11. An LED light bar structure, comprising:
a circuit board disposed at a side edge of a light guide plate and emitting lights toward the light guide plate;
a first row light source including a plurality of first LEDs arranged as one row by spacing a first interval;
a second row light source including a plurality of second LEDs arranged as one row by spacing a second interval; and
a third row light source including a plurality of third LEDs corresponding to the first LEDs of the first row light source;
wherein the second row light source is between the first row light source and the third row light source, and the first LEDs of the first row light source and the third LEDs of the third row light source alternately continue with the second LEDs of the second row light source along the longitude direction of the circuit board, so as to keep the lights entering into the light guide plate continuously.

12. The LED light bar structure according to claim 11, wherein the first interval is equal to the length of the second LEDs.

13. The LED light bar structure according to claim 11, wherein the first interval is smaller than the length of the second LEDs.

14. The LED light bar structure according to claim 11, wherein the second interval is equal to the length of the first LEDs.

15. The LED light bar structure according to claim 11, wherein the second interval is smaller than the length of the first LEDs.

16. The LED light bar structure according to claim 11, wherein the length of the fist LEDs is larger than the length of the second LEDs.

17. The LED light bar structure according to claim 11, wherein the length of the fist LEDs is smaller than the length of the second LEDs.
